(19) United States
(12) Patent Application Publication
(10) Pub. No.: US 2012/0023794 A1
(43) Pub. Date: Feb. 2, 2012

(54) PORTABLE SOLAR LIGHT FOR SPORTS ENTHUSIAST

(76) Inventors: Sue Ann Kerecman, Johnstown, OH (US); Jamie Dee Elerick, Johnstown, OH (US)

(21) Appl. No.: 12/848,997

(22) Filed: Aug. 2, 2010

(51) Int. Cl. G09F 13/04; H05K 13/00; F21L 4/08

(52) U.S. Cl. 40/552; 29/592.1

(57) ABSTRACT

The present lighting units provide an effective means by which a sports fan may express his support for a favorite team or school, whether it be a professional team, a collegiate team or college, or a high school team or high school. The portable lighting unit includes a housing having the appearance of a plurality of connected tiers, each of the tiers having a differing dimension such that the tiers convey a stair-step configuration. To represent the sports team or school, at least two three-dimensional alphabetic characters are affixed to a front surface of the tiers. A solar-powered lighting fixture is attached to the uppermost surface of the top tier to provide illumination for outdoor or indoor use. The housing and lettering may feature the team colors. A method of producing the lighting unit is also provided.

### BACKGROUND OF THE INVENTION

The present disclosure is directed to the field of portable lighting and, specifically, to solar lighting having a sports-related theme.

### SUMMARY

Many times, a sports fan may entertain friends and family at his home, particularly on game days when his favorite team is playing on television. At these occasions, the guests may enjoy a cook-out or picnic on a deck, porch, or patio before gathering indoors in a living room or den to watch the game. To decorate either the indoor or outdoor spaces for the game-day festivities, the sports fan may use signs, banners, memorabilia, or the like to convey his support for his favorite team.

Often, a patio, deck, or walkway may be illuminated by outdoor lighting, solar lighting, torches, and/or candles. However, none of the existing lighting devices offer the sports fan a way to effectively express his support and enthusiasm for his favorite team or school.

The present lighting units provide an attractive, eye-catching, and effective means by which a sports fan may express his support for a favorite team or school, whether it be a professional team, a collegiate team or college, or a high school team or high school. The portable lighting unit includes a housing having the appearance of a plurality of connected tiers, each of the tiers having a differing dimension such that the tiers convey a stair-step configuration. To represent the sports team or school, at least two three-dimensional alphabetic characters are affixed to a front surface of the tiers. A solar-powered lighting fixture is attached to the uppermost surface of the top tier to provide illumination for outdoor or indoor use.

The lighting unit provides illumination to a yard, walkway, patio, deck, or porch on which it is displayed and, because the lighting unit includes a solar-powered lighting fixture, it requires no external power sources or complicated installation. Conveniently, the lighting unit may be transported indoors for decorating the area in which the sporting event will be viewed. The lighting unit may feature one or more colors associated with the sports team or school, and may further feature a depiction of the team's mascot, logo, or insignia.

A method of producing a portable lighting unit for demonstrating support for a particular sports team is also provided herein. The method includes the steps of providing a housing having the appearance of a plurality of tiers connected together, each of the tiers having a differing dimension such that the tiers convey a stair-step configuration; affixing a solar-powered lighting fixture to an uppermost surface of a top tier; and applying at least two alphabetic characters to the front surfaces of two of the tiers, the alphabetic characters being selected to represent the particular sports team.

### BRIEF DESCRIPTION OF THE DRAWINGS

A full and detailed disclosure is set forth in the accompanying specification, which makes reference to the appended figures, in which:

FIG. 1 is a perspective view of a portable lighting unit for a sports enthusiast, in accordance with the teachings herein;

FIG. 2 is a plan view of the front of the portable lighting unit of FIG. 1;

FIG. 3 is a side view of the portable lighting unit of FIG. 1; and

FIG. 4 is a perspective view of an alternate configuration of a portable lighting unit for a sports enthusiast, as further contemplated herein.

### DETAILED DESCRIPTION OF THE DRAWINGS

Reference is now made to the drawings for illustration of various components of the present portable lighting units. While the particular illustrations provided herein are directed to portable lighting units having three tiers, various elements and embodiments are equally applicable to creating portable lighting units of other shapes and sizes. Moreover, while the tiers of the portable lighting units are described as being made of wood, the tiers may be made of other durable materials instead, such as plastic. In addition, although the lighting units are shown with solar light fixtures, hard-wired lighting fixtures could instead be used, if desired to mount the lighting unit in a single location.

While reference is made throughout the description to showing support for football teams, it should be understood that the portable lighting units provided herein could be used to indicate support for other types of athletic teams, such as baseball teams, basketball teams, hockey teams, soccer teams, and the like, as well as schools, colleges, or universities in general. Finally, it should also be noted that, while reference is made to use of the lighting units in a home environment, the lighting units may be equally well-suited for use in a tail-gating situation or in a business or commercial setting.

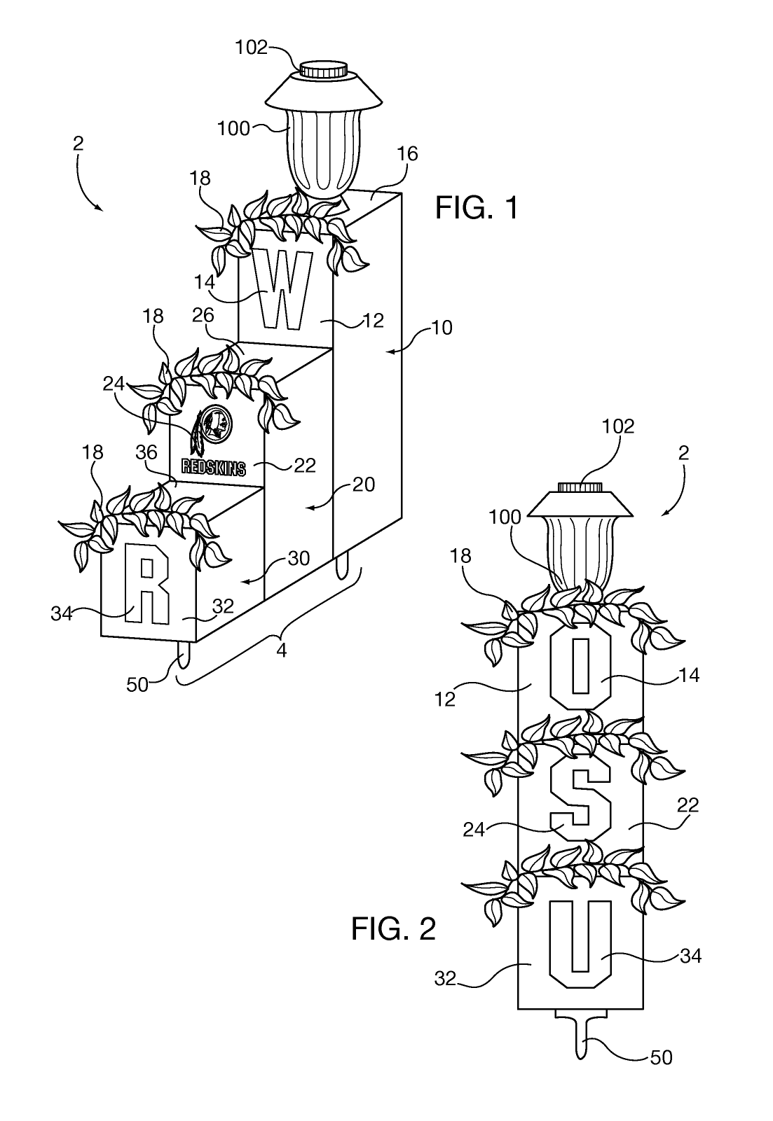

FIG. 1 illustrates a first version of a portable lighting unit 2, according to the teachings herein, which is configured to show support for a professional, collegiate, or high school sports team or organization. The portable lighting unit 2 may include a housing 4 in the form of three stacked tiers 10, 20, 30. The three tiers 10, 20, 30 are arranged by height to create a stair-step configuration. The first tier 10, in this illustration, is the tallest tier, while the second tier 20 is slightly shorter and the third tier 30 is the shortest. By way of example, the first tier 10 may have a height of approximately 18 inches; the second tier 20, a height of approximately 12 inches; and the third tier 30, a height of approximately 6 inches. The tiers 10, 20, 30 may be made of pressure-treated wood or molded plastic, and the tiers 10, 20, 30 may be solid, hollow, or semi-hollow. Alternately, instead of three separate tiers, the housing 4 may be unitary, such as a single molded piece of plastic constructed to appear as three different tiers.

A front surface 12 and an upper surface 16 of the first tier 10 may be of equal widths. One exemplary width is approximately 4.5 inches. The front surfaces 22, 32 and the upper surfaces 26, 36 of the second and third tiers 20, 30, respectively, may have a similar width to one another and to the dimensions of the first tier 10 to provide a consistent appearance to the lighting unit 2.

The upper surface 16 of the first tier 10 forms the uppermost surface of the lighting unit 2 and, as such, acts as the support for a solar-powered lighting fixture 100. The lighting fixture 100, which is affixed to the upper surface 16 by conventional means, provides decorative accent lighting for indoor or outdoor use. The lighting fixture 100 includes a solar-powered cell, or battery, 102. The lighting fixture 100 may be of any style or dimensions, depending on the tastes and preferences of the consumer, but one representative height for the lighting fixture 100 is about 5 inches.

A decorative element may be affixed, using one or more of an adhesive, nails, brads, staples, or rivets to the front surfaces 12, 22, 32 of each tier 10, 20, 30. The decorative element is three-dimensional and may be a letter (e.g., letters 14, 34) or a depiction of mascot, logo, or insignia 24 of a sports team or school. By way of example and not of limitation, the letters 14, 34 may have a height of between about three inches to about four inches, and the logo 24 may be similarly sized. The letters 14, 34 may be selected to represent a team name (for example, “N” and “O” for “New Orleans”) or may be selected to represent a team name and mascot (for example, “W” and “R” for “Washington Redskins”). Alternately, as shown in FIG. 2 and FIG. 4, three letters may be used to represent a school, such as “OSU” for The Ohio State University or “DHS” for “Davis High School,” in which case a depiction of a team mascot, insignia, or logo would be omitted.

The tiers 10, 20, 30 may display the primary and secondary colors of the team being represented. For instance, the first tier 10 and the third tier 30 may be the primary color of the team, while the intermediate second tier 20 may be the secondary color of the team. With reference to the lighting unit 2 shown in FIG. 1, which represents the Washington Redskins professional football team, the first and third tiers 10 may be burgundy, while the second tier 20 may be gold. Alternately, all three tiers 10, 20, 30 may have a single color, such as the primary color of the team. In the case of the Washington Redskins lighting unit 2 shown in FIG. 1, all three tiers 10, 20, 30 may be burgundy. The colors of the tiers may be achieved with corresponding paint colors or stains, if the housing 4 is made of wood, or with embedded pigments, colorants, or dyes, if the housing 4 is made of plastic.

The decorative elements 14, 24, 34 may be colored to coordinate with or to complement the colors used for the tiers 10, 20, 30. For instance, if the first and third tiers 10, 20 are colored in the primary color of the team, the decorative elements 14, 34 attached to those tiers may be colored in the secondary color of the team. Alternately, the decorative elements 14, 34 may be colored in a neutral color, such as black or white, for contrast. Another option is that the decorative elements 14, 24, and/or 34 may be decorated with a pattern associated with the team being supported, such as tiger stripes used to represent the Cincinnati Bengals professional football team.

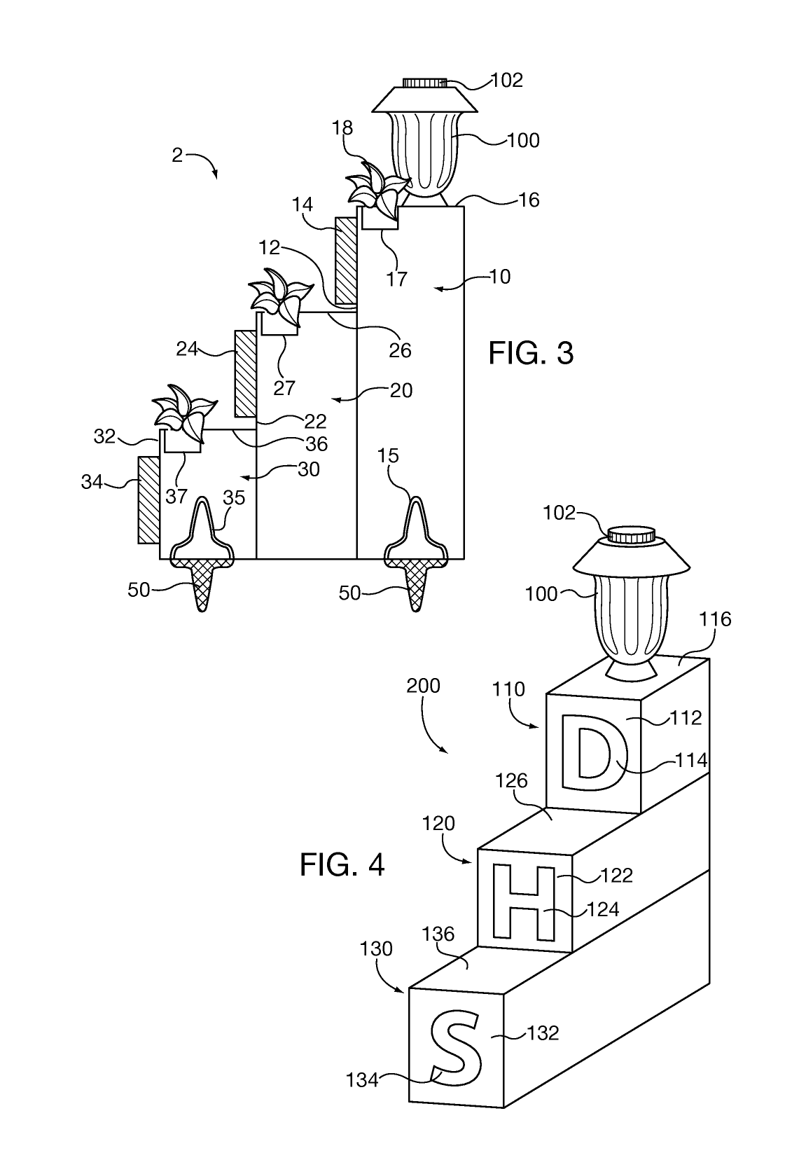

As shown in FIGS. 1 through 3, the bottom surface of the housing 4 may include one or more installation spikes or pins 50 for securing the lighting unit 2 in the ground. The spikes 50 may be molded from plastic or may be made of metal or another durable material. Although two spikes 50 are shown, other numbers (including one) of spikes 50 may be used. The installation spikes 50 may be removable to allow the unit 2 to be used indoors or on a flat outdoor surface, such as a deck, porch, or patio. In one version shown in FIG. 3, the bottom surface of the housing 4 may be provided with receptacles 15, 35, into which the installation spikes 50 may be inserted when not in use. Alternately, the spikes 50 may be secured with clips or screws for easy removal, such that the spikes 50 may be housed separately from the unit 2 when the spikes 50 are not needed.

Optionally, decorative foliage or vines 18, such as ivy, may be attached to the upper surfaces 16, 26, 36 of the tiers 10, 20, 30, as shown in FIGS. 1 through 3. These floral accents 18 may be used to provide a natural-looking element to the lighting unit 2. Although real plants may be used, the need for potting soil and drainage holes is eliminated when synthetic plants are employed. As shown in FIG. 3, the upper surfaces 16, 26, 36 of the tiers 10, 20, 30 may be molded or otherwise supplied with a trough 17, 27, 37 within which the decorative vines 18 may be planted or installed. The troughs 17, 27, 37 may house a piece of floral foam, if so desired. It may also be possible to eliminate the troughs 17, 27, 37 and attach the greenery 18 directly to the upper surfaces 16, 26, 36, using staples or hot glue.

An alternate configuration for a lighting unit 200 is shown in FIG. 4. In the lighting unit 200, the tiers 110, 120, 130 are arranged in a horizontal orientation based on the length of the tiers, such that the third tier 130 possesses the longest length, while the second and first tiers 120, 110 are progressively shorter to again produce a stair-step configuration. The result of this configuration is that a greater continuous surface area contacts the ground for potentially enhanced stability of the lighting unit 200.

The first tier 110 includes a front surface 112 to which a first decorative element 114 (the letter “D”) is attached and an upper surface 116 to which a lighting fixture 100 is secured. As before, the lighting fixture 100 includes a solar battery 102. The first tier 110 may have a representative length of about 4.5 inches, a representative height of about 6 inches, and a representative width of about 4.5 inches.

The second tier 120 includes a front surface 122 to which a second decorative element 124 (the letter “H”) is attached and an upper surface 126 that supports the first tier 110. By way of example, the second tier may have a length of about 9 inches, a height of about 6 inches, and a width of about 4.5 inches.

The third tier 130 includes a front surface 132 to which a third decorative element 134 (the letter “S”) is attached and an upper surface 136 that supports the second tier 120. Exemplary dimensions of the third tier 130 may be a length of about 13.5 inches, a height of about 6 inches, and a width of about 4.5 inches.

Although the lighting unit 200 of FIG. 4 is shown without the installation spikes 50, such spikes 50 may be included if so desired. Further, while the decorative elements 114, 124, 134 may represent a school name (such as “Davis High School”), different elements may be used. For example, the second element 124 may be replaced with a team mascot, insignia, or logo, such as an eagle, in which case the first element 114 may remain a letter (“D” for the school name) and the third element 134 may be replaced with a different letter (such as “E” for the mascot name, the eagle). Various other combinations may be used, as desired, including variations in which the first or third element is the team mascot, insignia, or logo. Finally, different dimensions other than those described may be used for all or some of the tiers 110, 120, 130.

A method of producing a portable lighting unit for demonstrating support for a particular sports team includes the steps of providing a housing having the appearance of a plurality of tiers connected together, each of the tiers having a differing dimension such that the tiers convey a stair-step configuration; affixing a solar-powered lighting fixture to an uppermost surface of a top tier; and applying at least two alphabetic characters to the front surfaces of two of the tiers, the alphabetic characters being selected to represent the particular sports team.

The method may further include providing three tiers for the lighting unit and arranging the three tiers in an upright orientation based on height to achieve the stair-step configuration. Alternately, three tiers having different lengths may be provided, and the three tiers may be arranged in a horizontal orientation based on length to achieve the stair-step configuration.

A first tier and a third tier may be colored in a first color, and a second tier positioned between the first tier and the third tier may be colored in a second color different from the first color, where the first color and the second color are the primary and secondary colors of the particular sports team. As described above, the alphabetic characters may be colored in the second color for contrast with the tiers.

The preceding discussion merely illustrates the principles of the present portable lighting units. It will thus be appreciated that those skilled in the art may be able to devise various arrangements, which, although not specifically shown or described herein, embody the principles of the invention and are included within its spirit and scope. Furthermore, all examples are conditional language recited herein are principally intended for educational purposes and to aid the reader in understanding the principles of the invention and the concepts contributed by the inventor to furthering the art and are to be construed as being without limitation to such specifically recited examples and conditions.

Moreover, all statements herein reciting principles, aspects, and embodiments of the invention, as well as specific examples thereof, are intended to encompass both structural and functional equivalents thereof. Additionally, it is intended that such equivalents include both currently known equivalents and equivalents developed in the future, i.e., any elements developed that perform the same function, regardless of structure.

This description of the exemplary embodiments is intended to be read in connection with the figures of the accompanying drawings, which are to be considered part of the entire description of the invention. The foregoing description provides a teaching of the subject matter of the appended claims, including the best mode known at the time of filing, but is in no way intended to preclude foreseeable variations contemplated by those of skill in the art.

What is claimed is:

1. A portable lighting unit for displaying support for a particular sports team, the portable lighting unit comprising: a housing having the appearance of a plurality of connected tiers, each of the tiers having a differing dimension such that the tiers convey a stair-step configuration; at least two three-dimensional alphabetic characters, the alphabetic characters being affixed to a front surface of the tiers and being selected to represent a sports team; and a solar-powered lighting fixture, the lighting fixture being attached to the uppermost surface of the top tier.

2. The portable lighting unit of claim 1, further comprising a three-dimensional depiction of one of a mascot, logo, and insignia of the sports team.

3. The portable lighting unit of claim 1, wherein the sports team is one of a professional sports team, a collegiate sports team, and a high school sports team.

4. The portable lighting unit of claim 1, wherein the alphabetic characters are the first letters of each word in a school name.

5. The portable lighting unit of claim 1, wherein the alphabetic characters are the first letters of the team name and mascot.

6. The portable lighting unit of claim 5, wherein the alphabetic characters display one of a primary color, a secondary color, and a pattern of the sports team.

7. The portable lighting unit of claim 1, wherein three tiers are connected to form the housing of the lighting unit.

8. The portable lighting unit of claim 7, wherein the three tiers are positioned in an upright orientation and are arranged based on height to achieve the stair-step configuration.

9. The portable lighting unit of claim 7, wherein the three tiers are positioned in a horizontal orientation and are arranged based on length to achieve the stair-step configuration.

10. The portable lighting unit of claim 7, wherein the three tiers are a first color and wherein the alphabetic characters are a second color different from the first color.

11. The portable lighting unit of claim 7, wherein a first of the three tiers and a third of the three tiers are a first color and wherein a second tier positioned between the first tier and the third tier is a second color different from the first color, the first and second colors being the primary and secondary colors of the sports team.

12. The portable lighting unit of claim 11, wherein the alphabetic characters are the second color.

13. The portable lighting unit of claim 1, wherein the tiers are made of wood or plastic.

14. The portable lighting unit of claim 1, further comprising a removable stake attached to a bottom surface of the tiers, the stake being configured for securing the lighting unit in the ground.

15. The portable lighting unit of claim 1, wherein each tier has an upper surface, the upper surfaces comprising a decorative plant material.

16. A method of producing a portable lighting unit for displaying support for a particular sports team, the method comprising: providing a housing having the appearance of a plurality of tiers connected together, each of the tiers having a differing dimension such that the tiers convey a stair-step configuration; affixing a solar-powered lighting fixture to an uppermost surface of a top tier; and applying at least two alphabetic characters to the front surfaces of two of the tiers, the alphabetic characters being selected to represent the particular sports team.

17. The method of claim 16, further comprising attaching a stake to a bottom surface of the tiers, the stake being configured for securing the lighting unit in the ground.

18. The method of claim 16, further comprising providing three tiers for the lighting unit and arranging the three tiers in an upright orientation based on height to achieve the stair-step configuration.

19. The method of claim 18, further comprising coloring a first tier and a third tier in a first color and coloring a second tier positioned between the first tier and the third tier in a second color different from the first color, the first color and the second color being the primary and secondary colors of the particular sports team.

20. The method of claim 19, further comprising coloring the alphabetic characters in the second color.
